(19) United States
(12) Patent Application Publication
(10) Pub. No.: US 2015/0091110 A1
(43) Pub. Date: Apr. 2, 2015

(54) Perpendicular Spin Transfer Torque Memory (STTM) Device with Coupled Free Magnetic Layers

(71) Applicants: Charles C. Kuo, Hillsboro, OR (US); Kaan Oguz, Hillsboro, OR (US); Mark L. Doczy, Portland, OR (US); Brian S. Doyle, Portland, OR (US); Satyarth Suri, Hillsboro, OR (US); Robert S. Chau, Portland, OR (US); David L. Kencke, Beaverton, OR (US); Roksana Golizadeh Mojarad, San Jose, CA (US); Anurag Chaudhry, Portland, OR (US)

(72) Inventors: Charles C. Kuo, Hillsboro, OR (US); Kaan Oguz, Hillsboro, OR (US); Mark L. Doczy, Portland, OR (US); Brian S. Doyle, Portland, OR (US); Satyarth Suri, Hillsboro, OR (US); Robert S. Chau, Portland, OR (US); David L. Kencke, Beaverton, OR (US); Roksana Golizadeh Mojarad, San Jose, CA (US); Anurag Chaudhry, Portland, OR (US)

(21) Appl. No.: 14/039,668

(22) Filed: Sep. 27, 2013

(51) Int. Cl. H01L 43/02; H01L 43/12

(52) U.S. Cl. CPC H01L 43/02; H01L 43/12
USPC 257/421

(57) ABSTRACT

Perpendicular spin transfer torque memory (STTM) devices with enhanced stability and damping are described. For example, a material layer stack for a magnetic tunneling junction includes a fixed magnetic layer. A dielectric layer is disposed above the fixed magnetic layer. A first free magnetic layer is disposed above the dielectric layer. A second free magnetic layer is magnetically coupled with the first free magnetic layer.

### TECHNICAL FIELD

Embodiments of the invention are in the field of memory devices and, in particular, perpendicular spin transfer torque memory (STTM) devices with coupled free magnetic layers to enhance stability and provide low damping.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory devices on a chip, lending to the fabrication of products with increased capacity. The drive for ever-more capacity, however, is not without issue. The necessity to optimize the performance of each device becomes increasingly significant.

The operation of spin torque devices is based on the phenomenon of spin transfer torque. If a current is passed through a magnetization layer, called the fixed magnetic layer, it will come out spin polarized. With the passing of each electron, its spin (angular momentum) will be transferred to the magnetization in the next magnetic layer, called the free magnetic layer, and will cause a small change on its magnetization. This is, in effect, a torque-causing precession of magnetization. Due to reflection of electrons, a torque is also exerted on the magnetization of an associated fixed magnetic layer. In the end, if the current exceeds a certain critical value (which is a function of damping caused by the magnetic material and its environment), the magnetization of the free magnetic layer will be switched by a pulse of current, typically in about 1-10 nanoseconds. Magnetization of the fixed magnetic layer may remain unchanged since an associated current is below its threshold due to geometry or due to an adjacent anti-ferromagnetic layer.

Spin-transfer torque can be used to flip the active elements in magnetic random access memory. Spin-transfer torque memory, or STTM, has the advantages of lower power consumption and better scalability over conventional magnetic random access memory (MRAM) which uses magnetic fields to flip the active elements. However, significant improvements are still needed in the area of STTM device manufacture and usage.

### BRIEF DESCRIPTION OF THE DRAWINGS

FIG. 1 illustrates a plot of damping versus thickness of a CoFeB layer in a material layer stack for a conventional spin transfer torque memory (STTM) device.

FIG. 2 illustrates a cross-sectional view of a material layer stack for a perpendicular STTM device, in accordance with an embodiment of the present invention.

FIG. 3 illustrates a diagram showing an example of coherent switching with magnetically coupled free layers in accordance with one embodiment of the present invention.

FIG. 4 illustrates a cross-sectional view of another material layer stack for a perpendicular STTM device, in accordance with another embodiment of the present invention.

FIG. 5 illustrates a plot 500 for measuring a damping value for a material stack in accordance with one embodiment of the invention.

FIG. 6 illustrates a cross-sectional view of another material layer stack for a perpendicular STTM device, in accordance with another embodiment of the present invention.

FIG. 7 illustrates a cross-sectional view of another material layer stack for a perpendicular STTM device, in accordance with another embodiment of the present invention.

FIG. 8 illustrates a schematic of a spin transfer torque memory bit cell which includes a spin transfer torque element, in accordance with an embodiment of the present invention.

FIG. 9 illustrates a block diagram of an electronic system, in accordance with an embodiment of the present invention.

FIG. 10 illustrates a computing device in accordance with one implementation of the invention.

### DESCRIPTION OF THE EMBODIMENTS

Perpendicular spin transfer torque memory (STTM) devices with coupled free magnetic layers to provide enhanced stability and low damping are described. In the following description, numerous specific details are set forth, such as specific magnetic layer integration and material regimes, in order to provide a thorough understanding of embodiments of the present invention. It will be apparent to one skilled in the art that embodiments of the present invention may be practiced without these specific details. In other instances, well-known features, such as integrated circuit design layouts, are not described in detail in order to not unnecessarily obscure embodiments of the present invention. Furthermore, it is to be understood that the various embodiments shown in the Figures are illustrative representations and are not necessarily drawn to scale.

One or more embodiments are directed to methodologies for increasing stability and reducing damping or maintaining a low damping in perpendicular STTM systems. Applications may include use in embedded memory, embedded non-volatile memory (NVM), magnetic random access memory (MRAM), magnetic tunnel junction (MTJ) devices, NVM, perpendicular MTJ, STTM, and non-embedded or stand-alone memories. In an embodiment, stability in perpendicular STTM devices is achieved by coupling a first free magnetic layer with a second free magnetic layer, as is described in greater detail below. The coupled free magnetic layers provide enhanced stability and low damping.

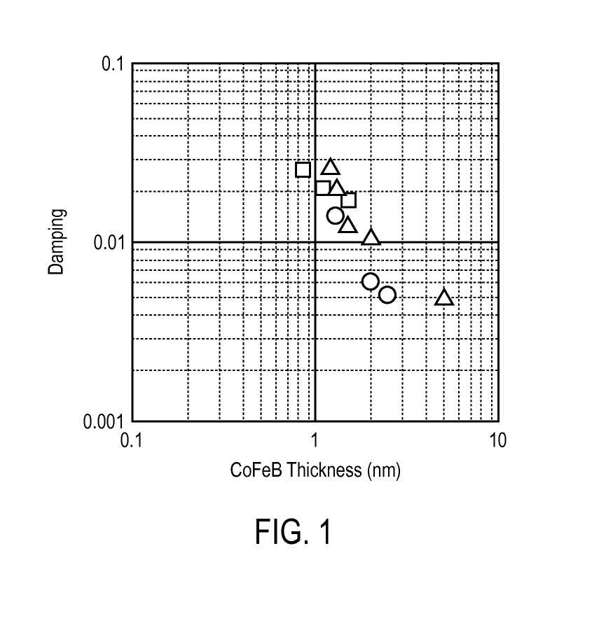

Stability is one of the most important issues facing scaling of STTM based devices and memory arrays fabricated there from. As scaling continues, the need for smaller memory elements to fit into a scaled cell size has driven the industry in the direction of perpendicular STTMs, which have higher stability for small memory element sizes. Common perpendicular STTMs are achieved with a material layer stack that includes a bottom electrode, a fixed magnetic layer, a dielectric layer (e.g., MgO), a free magnetic layer (e.g., CoFeB), a capping layer (e.g., Ta), and a top electrode. A magnetic tunnel junction (MTJ) portion of the material layer stack includes the fixed magnetic layer, the dielectric layer, and the free magnetic layer. This material stack is a basic material stack for fabricating STTM, and may be fabricated with greater complexity. For example, an anti-ferromagnetic layer may also be included between bottom electrode and fixed magnetic layer. Additionally, electrodes may themselves include multiple layers of material with differing properties. The material stack may, in its most basic form, be an in-plane system, where spins of the magnetic layers are in a same plane as the layers themselves. However, with layer or interface engineering, the material stack may be fabricated to provide a perpendicular spin system. In an example, a free magnetic layer, e.g., a free magnetic layer composed of CoFeB, is thinned down from a conventional thickness used for in-plane STTM devices. The extent of thinning may be sufficient such that a perpendicular component obtained from the iron/cobalt (Fe/Co) in the free magnetic layer interacting with oxygen in the dielectric layer (e.g., interacting with a magnesium oxide (MgO) layer) dominates over the in-plane component of the free CoFeB layer. This example provides a perpendicular system based on a single layer system of coupling to one interface of the free layer (i.e., the CoFeB—MgO interface). The degree of oxidation of surface iron/cobalt atoms (Fe/Co) in the CoFeB layer by oxygen from the MgO layer provides the strength (stability) of the free layer to have perpendicular-dominated spin states. This conventional stack fails to provide high stability and low damping. Stability is defined as the energy barrier between two magnetic states (e.g., (1, 0), (parallel, anti-parallel)). Stability is equal to the product of effective magnetic anisotropy, thickness of free magnetic layer, and area of free magnetic layer. Damping relates to a magnetic friction that a spin's magnetization experiences as the spin switches from one state to another. A larger damping means that a larger write current is needed. However, for the conventional material stack described above with a single free magnetic layer (e.g., CoFeB film), damping increases as CoFeB thickness in nanometers (nm) decreases as illustrated in FIG. 1 for different conventional material stacks. Thus, for higher stability that is represented by thinner CoFeB, the conventional material stack provides higher damping.

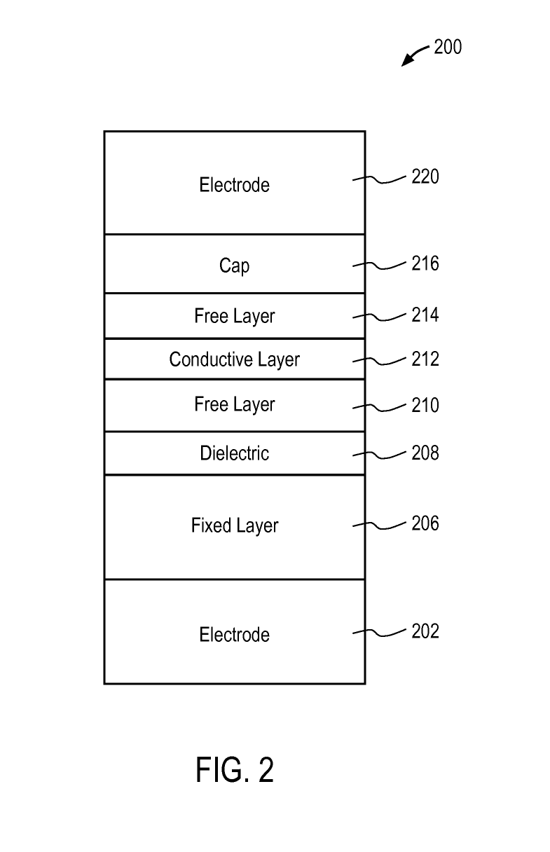

In another aspect, stability of a perpendicular nature or dominance of an STTM cell is enhanced along with providing reduced damping by the use of an additional free magnetic layer within the stack. As an example, FIG. 2 illustrates a cross-sectional view of a material layer stack for a perpendicular STTM device, in accordance with an embodiment of the present invention. Referring to FIG. 2, a material layer stack 200 for a perpendicular STTM device includes an electrode 202 (e.g., bottom electrode), a fixed magnetic layer 206, a dielectric layer 208, a free magnetic layer 210, a conductive layer 212, a free magnetic layer 214, a capping layer 216, and an electrode 220 (e.g., top electrode). In an embodiment, the material stack shown in FIG. 2 is a perpendicular system, where spins of the magnetic layers are perpendicular to the plane of the layers themselves. The dielectric layer 208 may be magnesium oxide (MgO). This layer 208 may have a resistance*area (RA) of approximately 10 ohm micron². MgO is a spin filtering tunneling dielectric used in MTJs. The dielectric layer also provides a crystallization template (e.g., BCC 001 orientation) for the free magnetic layer 210. In one embodiment, the free magnetic layer 210 is CoFeB. This layer may have a thickness of approximately 0.5-1.5 nm (e.g., 1 nm). This layer can be used as memory storage. The conductive layer 212 is a thin conductive film that includes at least one of the following: Ruthenium (Ru), Tantalum (Ta), Titanium (Ti), Zirconium (Zr), Hafnium (Hf), and Magnesium (Mg). The conductive layer 212 magnetically couples the free layers 210 and 214 together such that the conductive layer increases the effective thickness of the free layer 210, which improves the overall stability for the same given area. Note, the thickness of a single free layer can not be increased and achieve the same improvement in stability because a thicker CoFeB layer causes the magnetic anisotropy to drop from a perpendicular magnetization to an in-plane magnetization. The conductive layer also getters dopants from the free layers (e.g., getters Boron from CoFeB), which improves the crystallization of the free layers. Better free layer crystallinity improves stability and spin polarization. Also, the conductive layer should be just a few angstroms (e.g., significantly less than 1 nm) to minimize damping. A free layer 214 is magnetically coupled to free layer 210 in order to help increase Keff*t by increasing the overall thickness of the free layer. Examples of the free layer 214 include CoFeB (e.g., approximately 1 nm) or a multi-layer of ferromagnetic material (e.g., Co, CoFe) and nonmagnetic material (e.g., Pd, Pt) such as Co/Pd times n where n equals a number of layers and Co and Pd each have a thickness of approximately 0.3 nm. The conductive cap layer 216 is disposed above free layer 214 and can be used as a low damping material. The conductive cap layer may be a non-metal such as a conductive oxide like MgO or TaOx. For metallic caps, the preference is using materials with small spin mixing conductance, which minimizes damping. These are typically lighter elements with small atomic number (Z) such as Carbon (C), Ti, Al, TiN, TiAlN. However, the type of the capping film is not as critical if there is a sufficient thickness of free layer material (e.g., approximately 2 nm for CoFeB adjacent to a Ta capping layer). For thicker coupled free layers, capping layers made of heavier elements such as Ta or Ru are permissible. Thus, the selection of a capping layer is important in minimizing damping.

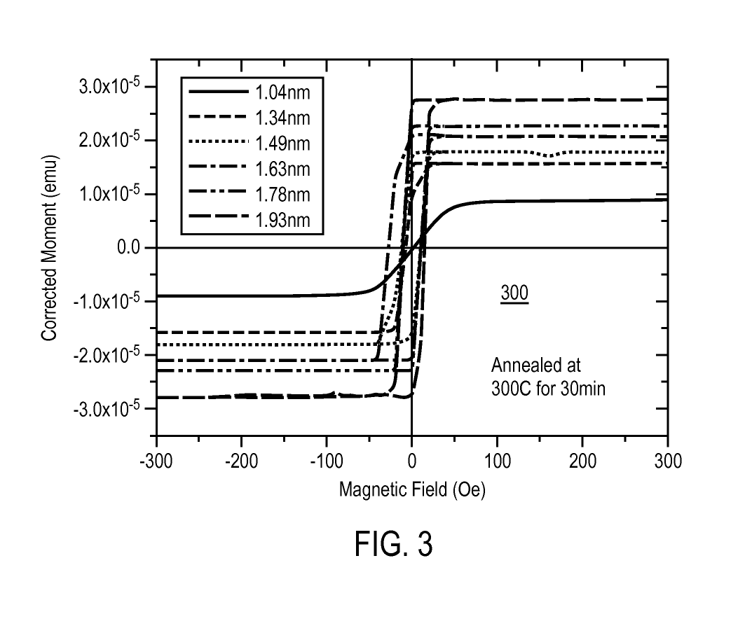

FIG. 3 illustrates a diagram showing an example of coherent switching with magnetically coupled free layers in accordance with one embodiment of the present invention. The diagram 300 shows correct moment (emu) versus magnetic field (Oe) for a material stack that includes SiO2, Mg, a first free layer, Ta, a second free layer, and MgO in which a total thickness of the two free layers (e.g., Co₂₀Fe₆₀B₂₀) is varied from 1.04 nm to 1.93 nm. The switching characteristics (e.g., sharper switching transition from first state to second state) improve as the total thickness of the two CoFeB is increased while still maintaining perpendicular magnetization.

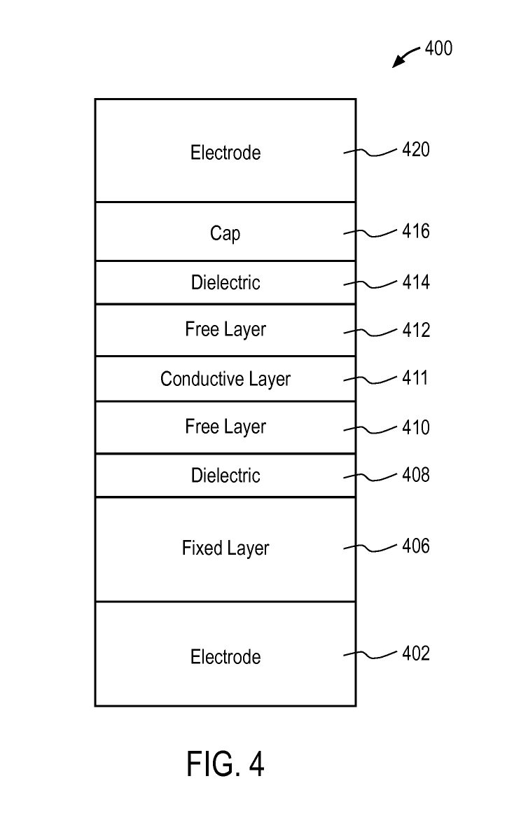

FIG. 4 illustrates a cross-sectional view of another material layer stack for a perpendicular STTM device, in accordance with another embodiment of the present invention. A material layer stack 400 for a perpendicular STTM device includes an electrode 402 (e.g., bottom electrode), a fixed magnetic layer 406 (e.g., CoFeB layer), a dielectric layer 408 (e.g., MgO layer of approximately 1 nm), a free magnetic layer 410 (e.g., CoFeB layer of approximately 1 nm), a conductive layer 411 (e.g., Ta layer of approximately 0.3 nm), a free magnetic layer 414 (e.g., CoFeB layer of approximately 1 nm), a dielectric layer 414 (e.g., MgO layer of approximately 0.7 nm), a capping layer 416, and an electrode 420 (e.g., top electrode). The thickness of dielectric layer 414 was chosen such that RA of dielectric layer 408 is significantly less than RA of dielectric layer 414. The free layers 410 and 412 are coupled together to achieve high stability. The thickness of the conductive layer 411 and a ratio of this thickness to a thickness of the free layers 410 and 412 can be designed to minimize damping. For example, in one embodiment, the conductive layer 411 has a thickness of approximately 0.3 nm and the free layers 410 and 412 each have a thickness of approximately 1 nm. A thickness ratio can ideally be increased to a certain extent to minimize damping, but this ratio is limited in that a thicker ratio will cause a loss of perpendicular magnetization. The thickness of the conductive film is designed as thin as possible with an upper limit of approximately 1 nm for Ta. The dual dielectric layers 408 and 414 (e.g., MgO layer of approximately 0.7 nm) at each end of the free layer stack suppress damping at the ends by eliminating spin-diffusion (i.e., spin pumping) from CoFeB into MgO. The stack 400 has been fabricated and damping has been determined to be near intrinsic values.

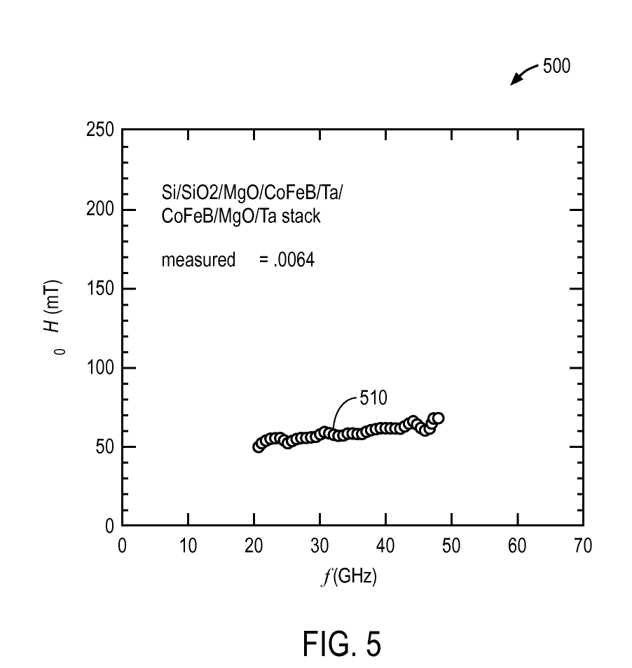

FIG. 5 illustrates a plot 500 for measuring a damping value for a material stack in accordance with one embodiment of the invention. The plot 500 illustrates ferromagnetic resonance for the material stack. The damping, alpha, (e.g., 0.0064) can be extracted from a slope of the curve 510. The material stack has an intrinsic damping value of approximately 0.005.

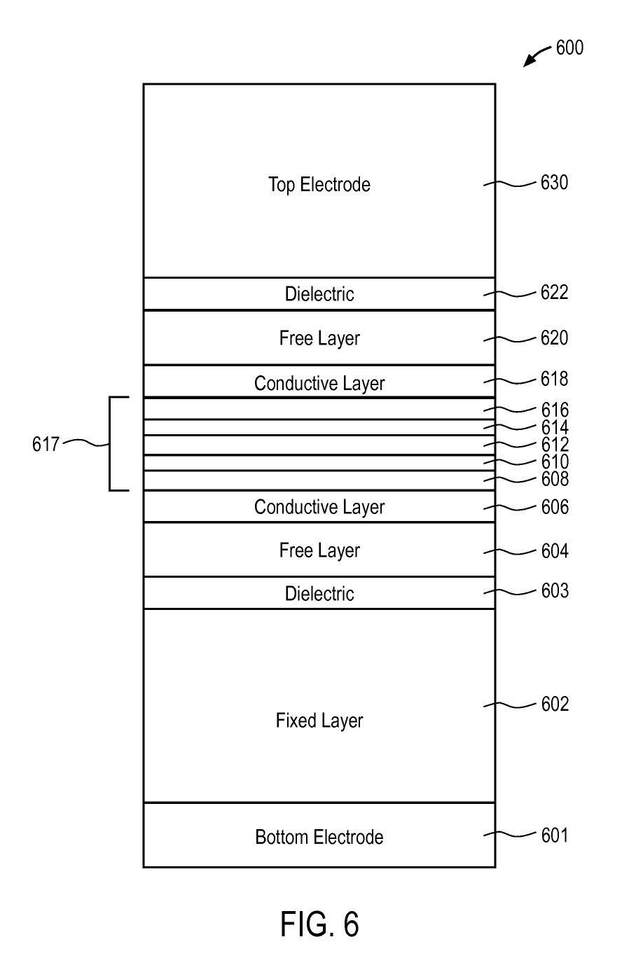

FIG. 6 illustrates a cross-sectional view of another material layer stack for a perpendicular STTM device, in accordance with another embodiment of the present invention. A material layer stack 600 for a perpendicular STTM device includes an electrode 601 (e.g., bottom electrode), a fixed magnetic layer 602 (e.g., CoFeB layer), a dielectric layer 603 (e.g., MgO layer of approximately 1 nm), a free magnetic layer 604 (e.g., CoFeB layer of approximately 1 nm), a conductive layer 606 (e.g., Ta layer of approximately 0.3 nm), and a multi-layer stack 617 that alternates ferromagnetic and non-magnetic layers. For example, the multi-layer stack 617 includes a non-magnetic layer 608 (e.g., Pd), a ferromagnetic layer 610 (e.g., Co), a non-magnetic layer 612 (e.g., Pd), a ferromagnetic layer 614 (e.g., Co), and a non-magnetic layer 616 (e.g., Pd). The multi-layer stack 617 acts as a second free magnetic layer. The stack 600 further includes a conductive layer 618 (e.g., approximately 0.3 nm of Ta), a free magnetic layer 620 (e.g., CoFeB layer of approximately 1 nm), a dielectric layer 622 (e.g., MgO layer of approximately 0.7 nm), and an electrode 630 (e.g., top electrode). Thus, the material stack includes three different free magnetic layers including the free magnetic layer 604, the multi-layer stack 617, and the free magnetic layer 620. Additional free magnetic layers and/or multi-layer stacks may be included.

The material stack 600 is similar to the material stack 400, except that a multi-layer 617 is inserted between the free (e.g., CoFeB)/conductive (e.g., Ta) layers. The strong perpendicular magnetization of the multi-layer stack enhances stability while maintaining a low damping value. Typically thickness values for Co/Pd are approximately 0.3 nm/0.3 nm since interface anisotropy is enhanced with thinner films and the Co:Pd ratio is kept small to minimize damping.

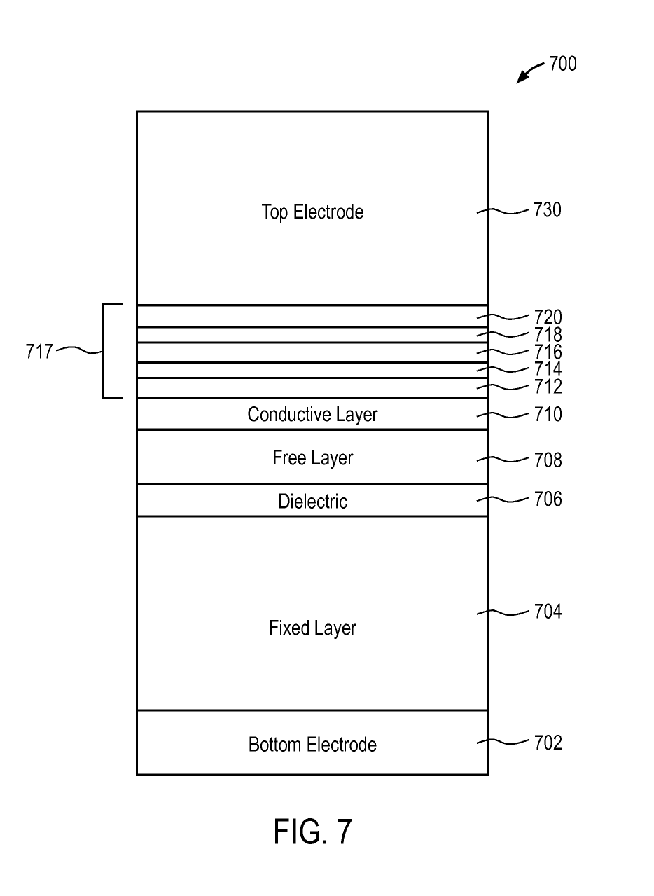

FIG. 7 illustrates a cross-sectional view of another material layer stack for a perpendicular STTM device, in accordance with another embodiment of the present invention. A material layer stack 700 for a perpendicular STTM device includes an electrode 702 (e.g., bottom electrode), a fixed magnetic layer 704 (e.g., CoFeB layer), a dielectric layer 706 (e.g., MgO layer of approximately 1 nm), a free magnetic layer 708 (e.g., CoFeB layer of approximately 1 nm), a conductive layer 710 (e.g., Ta layer of approximately 0.3 nm), and a multi-layer stack 717 that alternates ferromagnetic and non-magnetic layers. For example, the multi-layer stack 717 includes a non-magnetic layer 712 (e.g., Pd), a ferromagnetic layer 714 (e.g., Co), a non-magnetic layer 716 (e.g., Pd), a ferromagnetic layer 718 (e.g., Co), and a non-magnetic layer 720 (e.g., Pd). The stack 700 further includes an electrode 730 (e.g., top electrode).

The multi-layer stack 717 is magnetically coupled to the free layer 708 through the conductive layer 710. The Co, Pd, and conductive layer thickness are each kept to a few angstroms (e.g., approximately 0.3 nm) to ensure strong magnetic coupling, high stability, and low damping. The CoFeB and MgO remain thicker at approximately 1 nm as in previous examples.

In certain aspects and at least some embodiments of the present invention, certain terms hold certain definable meanings. For example, a “free” magnetic layer is a magnetic layer storing a computational variable. A “fixed” magnetic layer is a magnetic layer with fixed magnetization (magnetically harder than the free magnetic layer). A tunneling barrier, such as a tunneling dielectric (e.g., MgO) or tunneling oxide, is one located between free and fixed magnetic layers. A fixed magnetic layer may be patterned to create inputs and outputs to an associated circuit. Magnetization may be written by spin transfer torque effect while passing a current through the input electrodes. Magnetization may be read via the tunneling magneto-resistance effect while applying voltage to the output electrodes. In an embodiment, the role of the dielectric layer (e.g., dielectric layer 208) is to cause a large magneto-resistance ratio. The magneto-resistance is the ratio of the difference between resistances when the two ferromagnetic layers have anti-parallel magnetizations and the resistance of the state with the parallel magnetizations.

Referring to FIGS. 2, 4, 6, and 7 the portion of the spin transfer torque element 200, 400, 600, or 700 including the free magnetic layers, the dielectric layer (tunneling barrier layer), and the fixed magnetic layer is known as a magnetic tunneling junction. The free magnetic layers and the fixed magnetic layer may be ferromagnetic layers). The dielectric layer (tunneling barrier layer), which separates a lower free magnetic layer and the fixed magnetic layer, may have a thickness, e.g. a distance between the free magnetic layer and the fixed magnetic layer of about 1 nanometer or less, such that electrons can tunnel there through, if a bias voltage is applied between the top and bottom electrodes.

In an embodiment, the MTJ functions essentially as a resistor, where the resistance of an electrical path through the MTJ may exist in two resistive states, either “high” or “low,” depending on the direction or orientation of magnetization in the free magnetic layers and in the fixed magnetic layer. In the case that the spin direction is down (minority) in the free magnetic layer 210, a high resistive state exists, wherein direction of magnetization in the coupled free magnetic layers and the fixed magnetic layer are substantially opposed or anti-parallel with one another. In the case that the spin direction is up (majority) in the coupled free magnetic layers, a low resistive state exists, wherein the direction of magnetization in the coupled free magnetic layers and the fixed magnetic layer is substantially aligned or parallel with one another. It is to be understood that the terms “low” and “high” with regard to the resistive state of the MTJ are relative to one another. In other words, the high resistive state is merely a detectibly higher resistance than the low resistive state, and vice versa. Thus, with a detectible difference in resistance, the low and high resistive states can represent different bits of information (i.e. a “0” or a “1”).

The direction of magnetization in the coupled free magnetic layers may be switched through a process called spin transfer torque (“STT”) using a spin-polarized current. An electrical current is generally non-polarized (e.g. consisting of about 50% spin-up and about 50% spin-down electrons). A spin polarized current is one with a greater number of electrons of either spin-up or spin-down, which may be generated by passing a current through the fixed magnetic layer. The electrons of the spin polarized current from the fixed magnetic layer tunnel through the tunneling barrier or dielectric layer 208 and transfers its spin angular momentum to the free magnetic layer, wherein the free magnetic layer will orient its magnetic direction from anti-parallel to that of the fixed magnetic layer or parallel. The free magnetic layer may be returned to its original orientation by reversing the current.

Thus, the MTJ may store a single bit of information (“0” or “1”) by its state of magnetization. The information stored in the MTJ is sensed by driving a current through the MTJ. The free magnetic layer(s) does not require power to retain its magnetic orientations. As such, the state of the MTJ is preserved when power to the device is removed. Therefore, a spin transfer torque memory bit cell composed of the stack 200, 400, 600, or 700, respectively, is, in an embodiment, non-volatile.

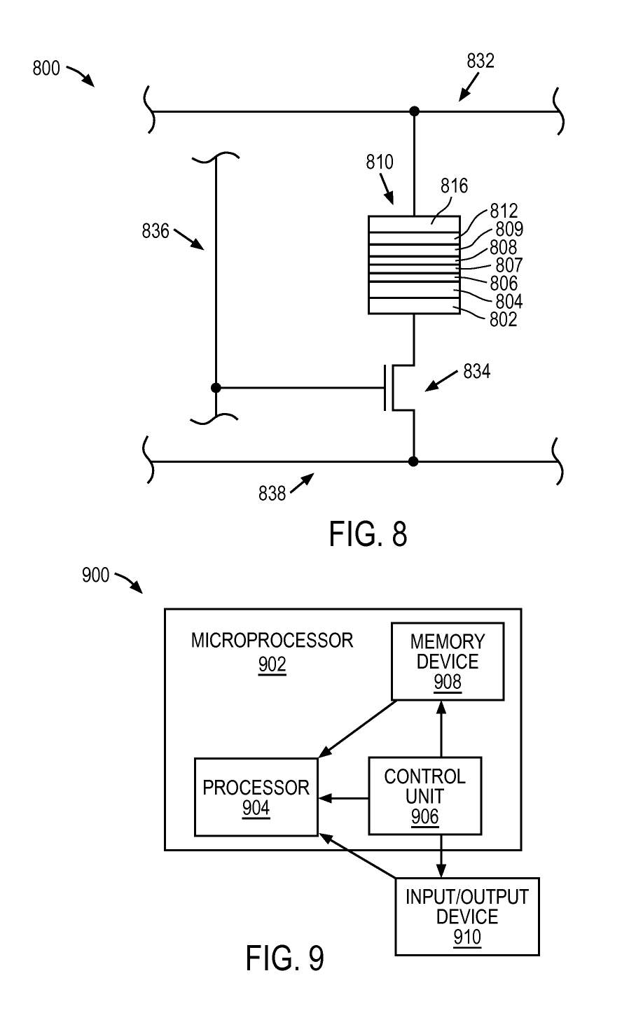

Referring again to the description associated with FIGS. 2, 3, 4, 6, and 7 a stack of layers including magnetic material layers which are used in a magnetic tunneling junction, may be used to fabricate as memory bit cell. For example, FIG. 8 illustrates a schematic of a spin transfer torque memory bit cell 800 which includes a spin transfer torque element 810, in accordance with an embodiment of the present invention.

Referring to FIG. 8, the spin transfer torque element 810 may include an electrode 802 (e.g., bottom electrode), a fixed magnetic layer 804 disposed above the electrode 802, a dielectric layer 806 disposed above the fixed magnetic layer, a first free magnetic layer 807 disposed above the dielectric layer, a conductive material layer 808 disposed between the first magnetic layer and a second free magnetic layer 809. The conductive material layer magnetically couples the second free magnetic layer magnetically with the first free magnetic layer. The element 810 (e.g., 200, 400, 600, 700) also includes a capping layer 812 and an electrode 816 (e.g., top electrode) disposed above the second free magnetic layer. A transistor 834 is electrically connected to the bottom electrode, a source line, and a word line as illustrated in FIG. 8. In another embodiment, the transistor 834 is electrically connected to the top electrode rather than the bottom electrode. In an embodiment, the spin transfer torque element 810 is based on perpendicular magnetism.

The top electrode 816 may be electrically connected to a bit line 832. The bottom electrode 802 may be coupled with a transistor 834. The transistor 834 may be coupled with a word line 836 and a source line 838 in a manner that will be understood to those skilled in the art. The spin transfer torque memory bit cell 800 may further include additional read and write circuitry (not shown), a sense amplifier (not shown), a bit line reference (not shown), and the like, as will be understood by those skilled in the art, for the operation of the spin transfer torque memory bit cell 800. It is to be understood that a plurality of the spin transfer torque memory bit cells 800 may be operably connected to one another to form a memory array (not shown), wherein the memory array can be incorporated into a non-volatile memory device. It is to be understood that the transistor 834 may be connected to the top electrode or the bottom electrode, although only the latter is shown.

FIG. 9 illustrates a block diagram of an electronic system 900, in accordance with an embodiment of the present invention. The electronic system 900 can correspond to, for example, a portable system, a computer system, a process control system, or any other system that utilizes a processor and an associated memory. The electronic system 900 may include a microprocessor 902 (having a processor 904 and control unit 906), a memory device 908, and an input/output device 910 (it is to be understood that the electronic system 900 may have a plurality of processors, control units, memory device units and/or input/output devices in various embodiments). In one embodiment, the electronic system 900 has a set of instructions that define operations which are to be performed on data by the processor 904, as well as, other transactions between the processor 904, the memory device 908, and the input/output device 910. The control unit 906 coordinates the operations of the processor 904, the memory device 908 and the input/output device 910 by cycling through a set of operations that cause instructions to be retrieved from the memory device 908 and executed. The memory device 908 can include a spin transfer torque element as described in the present description. In an embodiment, the memory device 908 is embedded in the microprocessor 902, as depicted in FIG. 9.

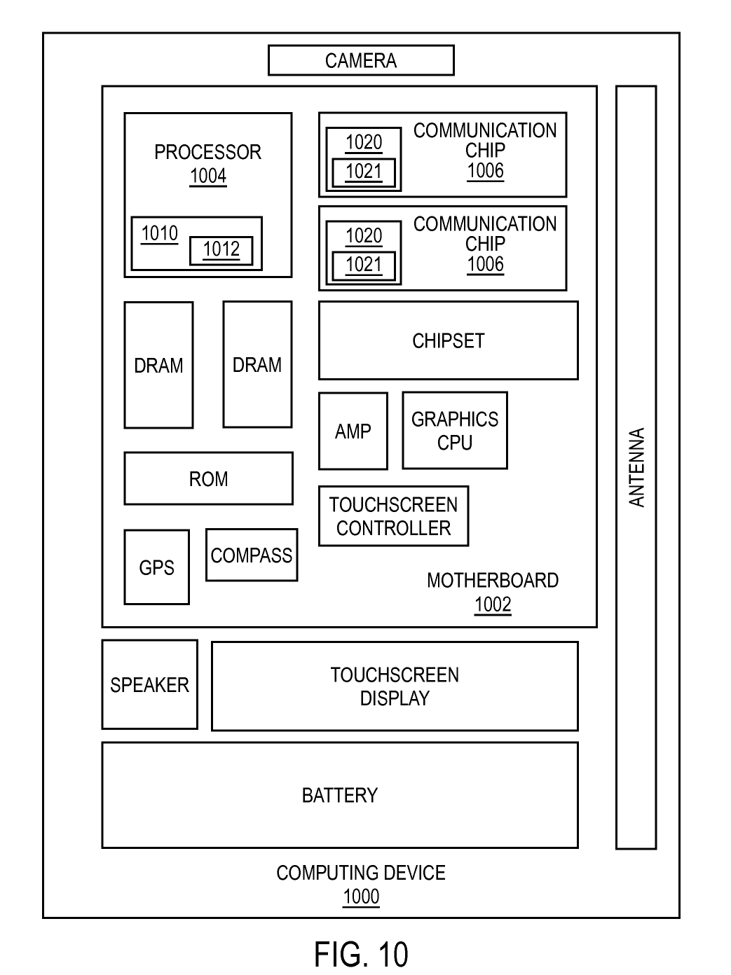

FIG. 10 illustrates a computing device 1000 in accordance with one implementation of the invention. The computing device 1000 houses a board 1002. The board 1002 may include a number of components, including but not limited to a processor 1004 and at least one communication chip 1006. The processor 1004 is physically and electrically coupled to the board 1002. In some implementations the at least one communication chip 1006 is also physically and electrically coupled to the board 1002. In further implementations, the communication chip 1006 is part of the processor 1004.

Depending on its applications, computing device 1000 may include other components that may or may not be physically and electrically coupled to the board 1002. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1006 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing device 1000 includes an integrated circuit die 1010 packaged within the processor 1004. In some implementations of the invention, the integrated circuit die of the processor includes one or more devices 1012, such as spin transfer torque memory built in accordance with implementations of the invention. The term “processor” may refer to any device or portion of a device that processes electronic data from registers and/or memory to transform that electronic data into other electronic data that may be stored in registers and/or memory.

The communication chip 1006 also includes an integrated circuit die 1020 packaged within the communication chip 1006. In accordance with another implementation of the invention, the integrated circuit die of the communication chip includes one or more devices 1021, such as spin transfer torque memory built in accordance with implementations of the invention.

In further implementations, another component housed within the computing device 1000 may contain an integrated circuit die that includes one or more devices, such as spin transfer torque memory built in accordance with implementations of the invention.

In various implementations, the computing device 1000 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1000 may be any other electronic device that processes data.

Accordingly, one or more embodiments of the present invention relate generally to the fabrication of microelectronic memory. The microelectronic memory may be non-volatile, wherein the memory can retain stored information even when not powered. One or more, embodiments of the present invention relate to a perpendicular spin transfer torque memory element for non-volatile microelectronic memory devices. Such an element may be used in an embedded non-volatile memory, either for its non-volatility, or as a replacement for embedded dynamic random access memory (eDRAM). For example, such an element may be used for 1T-1X memory (X=capacitor or resistor) at competitive cell sizes within a given technology node.

Thus, embodiments of the present invention include perpendicular spin transfer torque memory (STTM) devices with enhanced stability and low damping.

In an embodiment, a material layer stack for a magnetic tunneling junction includes a fixed magnetic layer, a dielectric layer disposed above the fixed magnetic layer, a first free magnetic layer disposed above the dielectric layer, and a second free magnetic layer magnetically coupled with the first free magnetic layer.

In one embodiment, a conductive material layer is disposed between the first and second free magnetic layers. The conductive material layer magnetically couples the first and second free magnetic layers to increase an effective thickness of the first free magnetic layer.

In one embodiment, the conductive material layer comprises at least one of the following: Ruthium (Ru), Tantalum (Ta), Titanium (Ti), Zirconium (Zr), Hafnium (Hf), and Magnesium (Mg).

In one embodiment, the first free magnetic layer comprises CoFeB, and wherein an interface between the dielectric layer and the first free magnetic layer provides a perpendicular magnetic component for the magnetic tunneling junction.

In one embodiment, the second free magnetic layer comprises CoFeB.

In one embodiment, the second free magnetic layer comprises one or more pairs of alternating ferromagnetic and non-magnetic layers disposed on the dielectric material layer. The alternating ferromagnetic and non-magnetic layers may include cobalt (Co) and palladium (Pd), respectively, with a Pd layer disposed on the conductive material layer.

In one embodiment, an additional dielectric layer is disposed above the second free magnetic layer. The dielectric layers may each comprise magnesium oxide (MgO).

In one embodiment, a non-volatile memory device includes a bottom electrode, a fixed magnetic layer disposed above the bottom electrode, a dielectric layer disposed above the fixed magnetic layer, a first free magnetic layer disposed above the dielectric layer, a second free magnetic layer magnetically coupled with the first free magnetic layer, a top electrode disposed above the second free magnetic layer, and a transistor electrically connected to the top or the bottom electrode, a source line, and a word line.

In one embodiment, the non-volatile memory device further includes a conductive material layer disposed between the first and second free magnetic layers. The conductive material layer magnetically couples the first and second free magnetic layers to increase an effective thickness of the first free magnetic layer.

In one embodiment, the conductive material layer comprises at least one of the following: Ruthium (Ru), Tantalum (Ta), Titanium (Ti), Zirconium (Zr), Hafnium (Hf), and Magnesium (Mg).

In one embodiment, the first free magnetic layer comprises CoFeB, and wherein an interface between the dielectric layer and the first free magnetic layer provides a perpendicular magnetic component for the magnetic tunneling junction.

In one embodiment, the second free magnetic layer comprises CoFeB.

In an embodiment, the second free magnetic layer comprises one or more pairs of alternating ferromagnetic and non-magnetic layers disposed on the dielectric material layer. The alternating ferromagnetic and non-magnetic layers may comprise cobalt (Co) and palladium (Pd), respectively, with a Pd layer disposed on the conductive material layer.

In one embodiment, the non-volatile memory device further includes an additional dielectric layer disposed above the second free magnetic layer, wherein the dielectric layers each comprise magnesium oxide (MgO).

In one embodiment, a material layer stack for a magnetic tunneling junction includes a fixed magnetic layer, a dielectric layer disposed above the fixed magnetic layer, a free magnetic layer disposed above the dielectric layer, and a multi-layer stack that alternates ferromagnetic and non-magnetic layers. The multi-layer stack is magnetically coupled with the free magnetic layer.

In one embodiment, the material layer stack further includes a conductive material layer disposed between the free magnetic layer and the multi-layer stack. The conductive material layer magnetically couples the free magnetic layer to the multi-layer stack to increase an effective thickness of the free magnetic layer.

In one embodiment, the conductive material layer comprises at least one of the following: Ruthium (Ru), Tantalum (Ta), Titanium (Ti), Zirconium (Zr), Hafnium (Hf), and Magnesium (Mg).

In one embodiment, the free magnetic layer comprises CoFeB, and wherein an interface between the dielectric layer and the free magnetic layer provides a perpendicular magnetic component for the magnetic tunneling junction.

In one embodiment, the alternating ferromagnetic and non-magnetic layers comprise cobalt (Co) and palladium (Pd), respectively, with a Pd layer disposed on the conductive material layer.

In one embodiment, the material layer stack further includes an additional free magnetic layer disposed above the multi-layer stack.

In one embodiment, the material layer stack, further includes an additional conductive material layer disposed between the additional free magnetic layer and the multi-layer stack. The conductive material layer magnetically couples the additional free magnetic layer to the multi-layer stack.

What is claimed is:

1. A material layer stack for a magnetic tunneling junction, the material layer stack comprising:
a fixed magnetic layer;
a dielectric layer disposed above the fixed magnetic layer;
a first free magnetic layer disposed above the dielectric layer; and
a second free magnetic layer magnetically coupled with the first free magnetic layer.

2. The material layer stack of claim 1, further comprising:
a conductive material layer disposed between the first and second free magnetic layers, the conductive material layer to magnetically couple the first and second free magnetic layers to increase an effective thickness of the first free magnetic layer.

3. The material layer stack of claim 2, wherein the conductive material layer comprises at least one of the following: Ruthium (Ru), Tantalum (Ta), Titanium (Ti), Zirconium (Zr), Hafnium (Hf), and Magnesium (Mg).

4. The material layer stack of claim 2, wherein the first free magnetic layer comprises CoFeB.

5. The material layer stack of claim 1, wherein the second free magnetic layer comprises CoFeB.

6. The material layer stack of claim 1, wherein the second free magnetic layer comprises one or more pairs of alternating ferromagnetic and non-magnetic layers disposed on the dielectric material layer.

7. The material layer stack of claim 6, wherein the alternating ferromagnetic and non-magnetic layers comprise cobalt (Co) and palladium (Pd), respectively, with a Pd layer disposed on the conductive material layer.

8. The material layer stack of claim 1, further comprising: an additional dielectric layer disposed above the second free magnetic layer, wherein the dielectric layers each comprise magnesium oxide (MgO).

9. A non-volatile memory device, comprising:
a bottom electrode;
a fixed magnetic layer disposed above the bottom electrode;
a dielectric layer disposed above the fixed magnetic layer;
a first free magnetic layer disposed above the dielectric layer;
a second free magnetic layer magnetically coupled with the first free magnetic layer;
a top electrode disposed above the second free magnetic layer; and
a transistor electrically connected to the top or the bottom electrode, a source line, and a word line.

10. The non-volatile memory device of claim 9, further comprising:
a conductive material layer disposed between the first and second free magnetic layers, the conductive material layer to magnetically couple the first and second free magnetic layers to increase an effective thickness of the first free magnetic layer.

11. The non-volatile memory device of claim 10, wherein the conductive material layer comprises at least one of the following: Ruthium (Ru), Tantalum (Ta), Titanium (Ti), Zirconium (Zr), Hafnium (Hf), and Magnesium.

12. The non-volatile memory device of claim 10, wherein the first free magnetic layer comprises CoFeB.

13. The non-volatile memory device of claim 9, wherein the second free magnetic layer comprises CoFeB.

14. The non-volatile memory device of claim 9, wherein the second free magnetic layer comprises one or more pairs of alternating ferromagnetic and non-magnetic layers disposed on the dielectric material layer.

15. The non-volatile memory device of claim 14, wherein the alternating ferromagnetic and non-magnetic layers comprise cobalt (Co) and palladium (Pd), respectively, with a Pd layer disposed on the conductive material layer.

16. The non-volatile memory device of claim 9, further comprising: an additional dielectric layer disposed above the second free magnetic layer, wherein the dielectric layers each comprise magnesium oxide (MgO).

17. A material layer stack for a magnetic tunneling junction, the material layer stack comprising:
a fixed magnetic layer;
a dielectric layer disposed above the fixed magnetic layer;
a free magnetic layer disposed above the dielectric layer; and
a multi-layer stack that alternates ferromagnetic and non-magnetic layers, the multi-layer stack is magnetically coupled with the free magnetic layer.

18. The material layer stack of claim 17, further comprising:
a conductive material layer disposed between the free magnetic layer and the multi-layer stack, the conductive material layer to magnetically couple the free magnetic layer to the multi-layer stack to increase an effective thickness of the free magnetic layer.

19. The material layer stack of claim 18, wherein the conductive material layer comprises at least one of the following: Ruthium (Ru), Tantalum (Ta), Titanium (Ti), Zirconium (Zr), Hafnium (Hf), and Magnesium.

20. The material layer stack of claim 17, wherein the free magnetic layer comprises CoFeB.

21. The material layer stack of claim 18, wherein the alternating ferromagnetic and non-magnetic layers comprise cobalt (Co) and palladium (Pd), respectively, with a Pd layer disposed on the conductive material layer.

22. The material layer stack of claim 17, further comprising:
an additional free magnetic layer disposed above the multi-layer stack.

23. The material layer stack of claim 22, further comprising:
an additional conductive material layer disposed between the additional free magnetic layer and the multi-layer stack, the conductive material layer to magnetically couple the additional free magnetic layer to the multi-layer stack.
